(19) United States
(12) Patent Application Publication
(10) Pub. No.: US 2024/0334834 A1
(43) Pub. Date: Oct. 3, 2024

(54) PIEZOELECTRIC ACTUATOR AND LIQUID DISCHARGING HEAD

(71) Applicant: BROTHER KOGYO KABUSHIKI KAISHA, Nagoya (JP)

(72) Inventors: Kakeru HIROTA, Nagoya (JP); Takashi AIBA, Nagoya (JP); Keiji KURA, Chita (JP); Taisuke MIZUNO, Yokkaichi (JP)

(73) Assignee: BROTHER KOGYO KABUSHIKI KAISHA, Nagoya (JP)

(21) Appl. No.: 18/583,981

(22) Filed: Feb. 22, 2024

(30) Foreign Application Priority Data
Apr. 3, 2023 (JP) 2023-059810

(51) Int. Cl. H10N 30/50; B41J 2/14; H10N 30/87

(52) U.S. Cl. CPC H10N 30/508; B41J 2/14274; H10N 30/871

(57) ABSTRACT

There is provided a piezoelectric actuator including: first to fourth piezoelectric layers and first to fifth electrodes. A part, of the first piezoelectric layer, between the first and second electrodes constitutes a first active part. A part, of the second piezoelectric layer, between the second and third electrodes constitutes a second active part. A part, of the third piezoelectric layer, between the third and fourth electrodes constitutes a third active part. Parts, of the first to fourth piezoelectric layers, between the first and fifth electrodes constitute two fourth active parts. A length of the third electrode is longer than a length of the second electrode and a length of the fourth electrode. Parts, of the first and second piezoelectric layers, between the first and third electrodes constitute two non-active parts. Parts, of the third and fourth piezoelectric layers, between the third and fifth electrodes constitute two fifth active parts.

### REFERENCE TO RELATED APPLICATIONS

This application claims priority from Japanese Patent Application No. 2023-059810 filed on Apr. 3, 2023. The entire content of the priority application is incorporated herein by reference.

### BACKGROUND ART

There is a known piezoelectric actuator provided with five electrodes arranged at mutually different positions in a first direction which is a stacking direction of piezoelectric layers.

### SUMMARY

A piezoelectric actuator disclosed in Japanese Patent Application Laid-open No. 2009-083336 is configured such that first active parts S11, S12 and S13a each corresponding to a central part of a pressure chamber and second active parts S21 and S22 each corresponding to a part on an outer circumferential part with respect to the central part of the pressure chamber are deformed in mutually opposite directions by the application of a voltage thereto. Thus, even in a case that the arrangement of pressure chambers is highly densified, the deformation of the first active parts propagating to adjacent pressure chamber is cancelled by the deformation of the second active parts, and consequently it is possible to suppress any crosstalk.

In Japanese Patent Application Laid-open No. 2009-083336, two electrodes 21B and 22A positioned at the central part of the pressure chamber have mutually same lengths in the X direction.

In the configuration of Japanese Patent Application Laid-open No. 2009-083336, in a case of manufacturing the piezoelectric actuator, the configuration of the active parts tends to easily change due to any positional deviation among the five electrodes. Accordingly, the configuration of the active parts is different among the manufactured piezoelectric actuators, which in turn leads to a variation in the deforming characteristic among the piezoelectric actuators. Further, depending on the configuration of the active parts, a change in the deforming characteristic following the increase in number of times of deformations might be great.

An object of the present disclosure is to provide a piezoelectric actuator and a liquid discharging head each capable of suppressing a variation in the deforming characteristic among individual piezoelectric actuators and capable of suppressing a chronological change in the deforming characteristic of the piezoelectric actuator.

According to an aspect of the present disclosure, there is provided a piezoelectric actuator including:
a first piezoelectric layer, a second piezoelectric layer, a third piezoelectric layer and a fourth piezoelectric layer stacked in a first direction in an order of the first piezoelectric layer, the second piezoelectric layer, the third piezoelectric layer, and the fourth piezoelectric layer; and
a first electrode arranged on a surface, of the first piezoelectric layer, on a side opposite to a side at which the second piezoelectric layer is arranged, a second electrode arranged between the first piezoelectric layer and the second piezoelectric layer, a third electrode arranged between the second piezoelectric layer and the third piezoelectric layer, a fourth electrode arranged between the third piezoelectric layer and the fourth piezoelectric layer, and a fifth electrode arranged on a surface, of the fourth piezoelectric layer, on a side opposite to a side at which the third piezoelectric layer is arranged, wherein:
the first to fifth electrodes are configured such that a high potential and a low potential lower than the high potential are selectively applied to the first electrode, the high potential is applied to the second electrode, the high potential and the low potential are selectively applied to the third electrode, the high potential is applied to the fourth electrode, and the low potential is applied to the fifth electrode;
a part, of the first piezoelectric layer, interposed between the first electrode and the second electrode in the first direction constitutes a first active part;
a part, of the second piezoelectric layer, interposed between the second electrode and the third electrode in the first direction constitutes a second active part;
a part, of the third piezoelectric layer, interposed between the third electrode and the fourth electrode in the first direction constitutes a third active part;
parts, of the first, second, third, and fourth piezoelectric layers, interposed between the first electrode and the fifth electrode in the first direction constitute two fourth active parts, the first, second, and third active parts being interposed between the two fourth active parts in a second direction orthogonal to the first direction;
a length in the second direction of the third electrode is longer than a length in the second direction of the second electrode, and is longer than a length in the second direction of the fourth electrode;
parts, of the first and second piezoelectric layers, interposed between the first electrode and the third electrode in the first direction constitute two non-active parts, each of the two non-active parts being interposed between one of the two fourth active parts and the first and second active parts in the second direction; and
parts, of the third and fourth piezoelectric layers, interposed between the third electrode and the fifth electrode in the first direction constitute two fifth active parts, each of the two fifth active parts being interposed between one of the two fourth active parts and the third active part in the second direction and being overlapped with one of the two non-active parts in the first direction.

According to another aspect of the present disclosure, there is provided a liquid discharging head including:
a channel member in which a channel including a nozzle and a pressure chamber communicating with the nozzle is formed; and
a piezoelectric actuator arranged in a surface, of the channel member, in which the pressure chamber is opened, wherein:
the piezoelectric actuator includes:
   a first piezoelectric layer, a second piezoelectric layer, a third piezoelectric layer and a fourth piezoelectric layer stacked in a first direction in an order of the first piezoelectric layer, the second piezoelectric layer, the third piezoelectric layer, and the fourth piezoelectric layer; and
   a first electrode arranged on a surface, of the first piezoelectric layer, on a side opposite to a side at which the second piezoelectric layer is arranged, a second electrode arranged between the first piezoelectric layer and the second piezoelectric layer, a third electrode arranged between the second piezoelectric layer and the third piezoelectric layer, a fourth electrode arranged between the third piezoelectric layer and the fourth piezoelectric layer, and a fifth electrode arranged on a surface, of the fourth piezoelectric layer, on a side opposite to a side at which the third piezoelectric layer is arranged;
the first to fifth electrodes are configured such that a high potential and a low potential lower than the high potential are selectively applied to the first electrode, the high potential is applied to the second electrode, the high potential and the low potential are selectively applied to the third electrode, the high potential is applied to the fourth electrode, and the low potential is applied to the fifth electrode;
a part, of the first piezoelectric layer, interposed between the first electrode and the second electrode in the first direction constitutes a first active part;
a part, of the second piezoelectric layer, interposed between the second electrode and the third electrode in the first direction constitutes a second active part;
a part, of the third piezoelectric layer, interposed between the third electrode and the fourth electrode in the first direction constitutes a third active part;
parts, of the first, second, third, and fourth piezoelectric layers, interposed between the first electrode and the fifth electrode in the first direction constitute two fourth active parts, the first, second, and third active parts being interposed between the two fourth active parts in a second direction orthogonal to the first direction;
a length in the second direction of the third electrode is longer than a length in the second direction of the second electrode, and is longer than a length in the second direction of the fourth electrode;
parts, of the first and second piezoelectric layers, interposed between the first electrode and the third electrode in the first direction constitute two non-active parts, each of the two non-active parts being interposed between one of the two fourth active parts and the first and second active parts in the second direction;
parts, of the third and fourth piezoelectric layers, interposed between the third electrode and the fifth electrode in the first direction constitute two fifth active parts, each of the two fifth active parts being interposed between one of the two fourth active parts and the third active part in the second direction and being overlapped with one of the two non-active parts in the first direction; and
the pressure chamber is not overlapped with the fourth active part in the first direction, and is overlapped with the first active part, the second active part, the third active part and each of the two fifth active parts in the first direction.

### BRIEF DESCRIPTION OF DRAWINGS

FIG. 1 is a view depicting the overall configuration of a printer 1 including a head 3 provided with a piezoelectric actuator 22.

FIG. 2 is a plan view of the head 3 of FIG. 1.

FIG. 3 is a cross-sectional view of the head 3 along a III-III line of FIG. 2.

FIG. 4 is a cross-sectional view of the head 3 along a IV-IV line of FIG. 2.

FIGS. 5A and 5B are each a view depicting an operation of an actuator part 60 in a cross section of FIG. 4.

FIGS. 6A and 6B are each a conceptual view indicating a change in a deforming characteristic of the actuator part 60.

FIG. 7 is a cross-sectional view depicting a piezoelectric actuator 222, corresponding to FIG. 4.

### DESCRIPTION

In the following explanation, a Z direction is the vertical direction, an X direction and a Y direction are each the horizontal direction. The X direction and the Y direction are both orthogonal to the Z direction. The X direction is orthogonal to the Y direction. The Z direction is an example of a “first direction”, and the X direction is an example of a “second direction”.

### First Embodiment

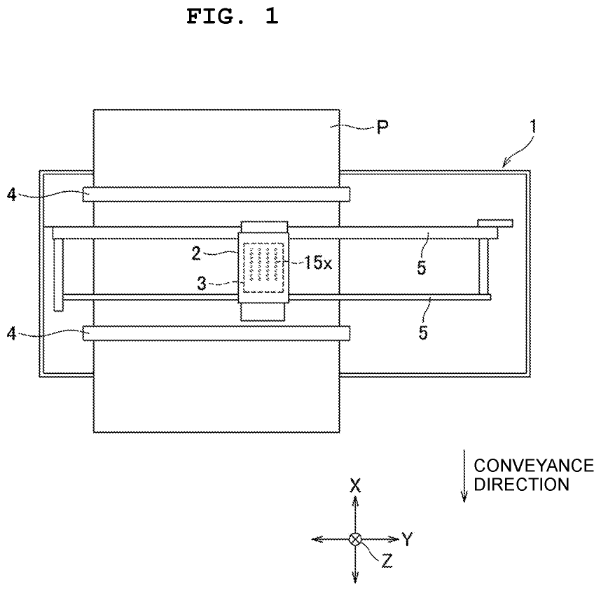

First, an explanation will be given about the overall configuration of a printer 1 including a head 3 (an example of a “liquid discharging head”) provided with a piezoelectric actuator 22 according to a first embodiment of the present disclosure, with reference to FIG. 1.

The printer 1 is provided with the head 3, a carriage 2 and two conveying roller pairs 4.

The carriage 2 is supported by two guide rails 5 extending in the Y direction, and is movable along the two guide rails 5 in the Y direction.

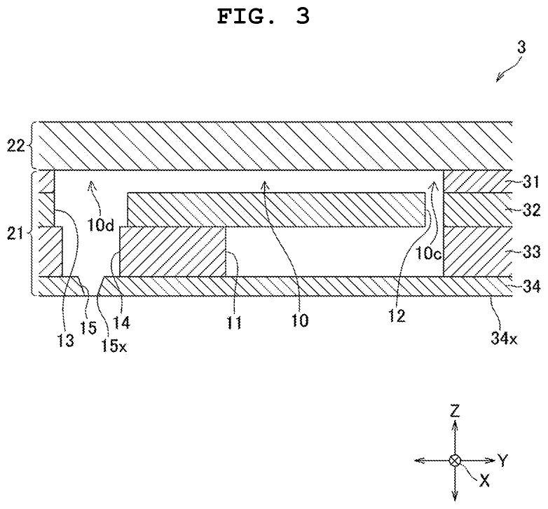

The head 3 is of a serial system, is mounted on the carriage 2, and is movable in the Y direction together with the carriage 2. A plurality of discharge ports 15X is opened in a lower surface of the head 3. Each of the plurality of discharge ports 15X is an opening at a forward end of a nozzle 15 depicted in FIG. 3.

The two conveying roller pairs 4 are arranged so that the carriage 2 is interposed between the two conveying roller pairs 4 in the X direction. Each of the two conveying roller pairs 4 includes two rollers arranged so as to face in the up-down direction. In a case that the two rollers of each of the two conveying roller pairs 4 rotate in a state that the two rollers of each of the two conveying roller pairs 4 pinch a paper P, the paper P is conveyed in a conveyance direction along the X direction.

A controller (not depicted in the drawings) of the printer 1 alternately performs a discharge (ejection) operation of discharging (ejecting) an ink from the nozzles 15 while moving the head 3 together with the carriage 2, in the Y direction, and a conveyance operation of conveying the paper P in the conveyance direction by a predefined amount with the two conveying roller pairs 4. With this, an image is recorded on the paper P.

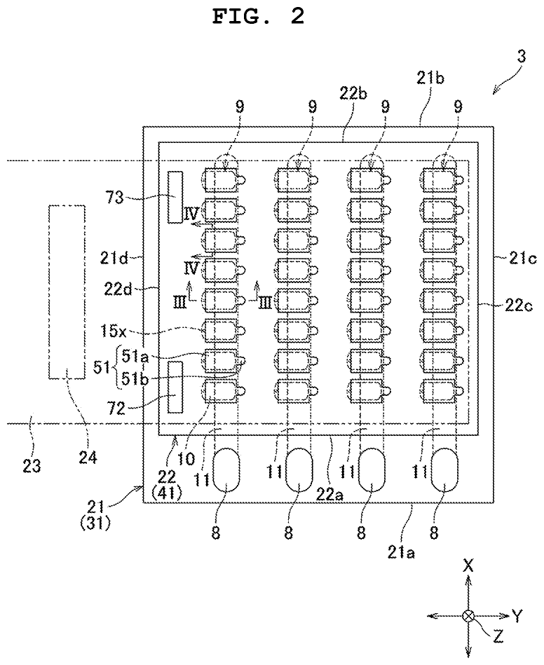

Next, the configuration of the head 3 will be explained, with reference to FIG. 2 to FIGS. 6A, 6B.

As depicted in FIG. 2, the head 3 includes a channel member 21, the piezoelectric actuator 22 and a COF (Chip On Film) 23.

The channel member 21 has a rectangular shape as seen in the Z direction, and has two sides 21a and 21b each extending along the Y direction and two sides 21c and 21d each extending along the X direction.

The piezoelectric actuator 22 has a rectangular shape as seen in the Z direction, like the channel member 21, and has two sides 22a and 22b each extending along the Y direction and two sides 22c and 22d each extending along the X direction. The piezoelectric actuator 22 has a size which is one size smaller than the channel member 21, as seen in the Z direction.

As depicted in FIG. 3, the channel member 21 is constructed of four plates 31 to 34 stacked in the Z direction.

As depicted in FIG. 2 and FIG. 3, a plurality of pressure chambers 10 is formed in the plate 31. As depicted in FIG. 2, each of the plurality of pressure chambers 10 has a shape which is substantially rectangular as seen in the Z direction, and has a length in the Y direction which is longer than a length in the X direction. The plurality of pressure chambers 10 constructs four pressure chamber rows 9. The four pressure chamber rows 9 are arranged side by side in the Y direction. Each of the four pressure chamber rows 9 has eight pressure chambers 12 which are arranged in the X direction, at equal spacing distances therebetween.

As depicted in FIG. 2 and FIG. 3, a plurality of through holes 12 and a plurality of through holes 13 are formed so that each of the plurality of through holes 12 and each of the plurality of through holes 13 correspond to one of the plurality of pressure chambers 10. Each of the plurality of through holes 12 is overlapped in the Z direction with an area 10c at one side in the Y direction of the corresponding pressure chamber 10. Each of the plurality of through holes 13 is overlapped in the Z direction with an area 10d at the other side in the Y direction of the corresponding pressure chamber 10. A cross-sectional area, of each of the plurality of through holes 12, orthogonal to the Z direction is smaller than a cross-sectional area, of the pressure chamber 10, orthogonal to the Y direction. Each of the plurality of through holes 12 functions as a throttle channel.

As depicted in FIG. 2 and FIG. 3, a plurality of through holes 14 is formed so that each of the plurality of through holes 14 corresponds to one of the plurality of through holes 13. Each of the plurality of through holes 14 is overlapped, in the Z direction, with the corresponding through hole 13.

As depicted in FIG. 2 and FIG. 3, four manifold channels 11 are further formed in the plate 33. As depicted in FIG. 2, the four manifold channels 11 correspond respectively to the four pressure chamber rows 9. Each of the four manifold channels 11 extends in the X direction, and has parts overlapped, in the Z direction, with the eight pressure chambers 10 of the corresponding pressure chamber row 9. Each of the four manifold channels 11 communicates with the eight pressure chambers 10 of the corresponding pressure chamber row 9, via the plurality of through holes 12.

Four ink supply ports 8 are formed, in the upper surface of the plate 31, at an area in which the piezoelectric actuator 22 is not arranged (see FIG. 2). The four ink supply ports 8 correspond, respectively, to the four manifold channels 11. Each of the four ink supply ports 8 is arranged at a position overlapped with an end in the X direction (a lower end in FIG. 2) of the corresponding manifold channel 11. The ink is supplied to the four manifold channels 11 from the four ink supply ports 8, respectively.

As depicted in FIG. 2 and FIG. 3, a plurality of through holes each of which constructs one of the plurality of nozzles 15 is formed in the plate 34. Each of the plurality of nozzles 15 is overlapped with one of the plurality of through holes 14 in the Z direction. Each of the plurality of nozzles 15 communicates with the corresponding pressure chamber 10 via the corresponding through hole 13 and the corresponding through hole 14.

The ink supplied to each of the four manifold channels 11 flows in the through hole 12 upward in the Z direction, and flows into each of the plurality of pressure chambers 10. The ink flows inside the pressure chamber 10 along the Y direction from the area 10c at the one end toward the area 10d at the other end, flows in the through holes 13 and 14 downward in the Z direction, and is discharged from the discharge port 15x at the forward end of the nozzle 15.

As depicted in FIG. 3, the piezoelectric actuator 22 is positioned at a location above the channel member 21 in the Z direction, and is arranged on the upper surface of the plate 31. The upper surface of the plate 31 is a surface, in the channel member 21, in which the plurality of pressure chambers 10 are opened.

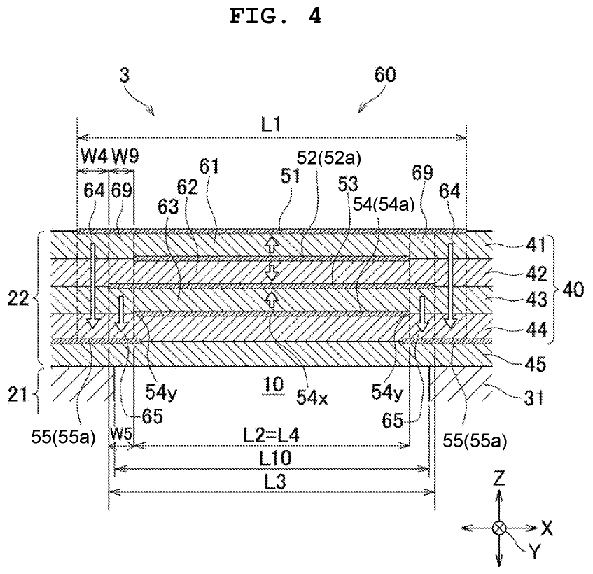

As depicted in FIG. 4, the piezoelectric actuator 22 has a piezoelectric body 40, an ink separating layer 45 and electrodes 51 to 55.

The piezoelectric body 40 includes a first piezoelectric layer 41, a second piezoelectric layer 42, a third piezoelectric layer 43 and a fourth piezoelectric layer 44 which are stacked in this order from the upper side in the Z direction. The piezoelectric layers 41 to 44 are each formed of a piezoelectric material composed primarily of lead zirconate titanate.

The ink separating layer 45 is arranged on the upper surface of the plate 31 and covers all the pressure chambers 10 formed in the plate 31. The ink separating layer 45 is formed, for example, of a metallic material such as stainless steel, etc., a piezoelectric material composed primarily of lead zirconate titanate, a synthetic resin material, etc.

The piezoelectric layers 41 to 44 and the ink separating layer 45 have mutually same shapes and size as seen in the Z direction, and define an outer shape of the piezoelectric actuator 22 which is rectangular-shaped as seen in the Z direction, as depicted in FIG. 2.

The electrodes 51 to 55 includes a driving electrode 51, a high potential electrode 52, a driving electrode 53, a high potential electrode 54 and a low potential electrode 55, as depicted in FIG. 4. The electrodes 51 to 55 are arranged at mutually different positions in the Z direction. Specifically, the driving electrode 51, the high potential electrode 52, the driving electrode 53, the high potential electrode 54 and the low potential electrode 55 are arranged in this order from the upper side in the Z direction.

The electrodes 51 to 55 are electrically connected to a wiring of the COF 23 (see FIG. 2). A driver IC 24 mounted on the COF 23 applies a potential to each of the electrodes 51 to 55, via the wiring of the COF 23. A high potential (VDD potential) and a low potential (GND potential) are selectively applied to each of the driving electrodes 51 and 53. The high potential (VDD potential) is applied to each of the high potential voltages 52 and 54. The low potential (GND potential) is applied to the low potential voltage 55. The low potential (GND potential) is a potential lower than the high potential (VDD potential).

The driving electrodes 51 and 53 are provided individually with respect to each of the plurality of pressure chambers 10 (see the driving electrode 51 of FIG. 2). The high potential electrode 52 has an individual part 52a which is provided individually with respect to each of the plurality of pressure chambers 10, and a connecting part (not depicted) which connects the individual parts 52a with one another. The high potential electrode 54 has an individual part 54a which is provided individually with respect to each of the plurality of pressure chambers 10, and a connecting part (not depicted) which connects the individual parts 54a with one another. The high potential electrode 55 has an individual part 55a which is provided individually with respect to each of the plurality of pressure chambers 10, and a connecting part (not depicted) which connects the individual parts 55a with one another.

The driving electrode 51 is an example of a “first electrode”, the individual part 52a of the high potential electrode 52 is an example of a “second electrode”, the driving electrode 53 is an example of a “third electrode”, the individual part 54a of the high potential electrode 54 is an example of a “fourth electrode”, and the individual part 55a of the low potential electrode 55 is an example of a “fifth electrode”.

The driving electrode 51 is arranged on the upper surface of the first piezoelectric layer 41, the upper surface being a surface, of the first piezoelectric layer 41, on a side opposite to a side at which the second piezoelectric layer 42 is arranged. The driving electrode 51 has an overlap part overlapped with the pressure chamber 10 in the Z direction, and outside parts which are not overlapped with the pressure chamber 10 in the Z direction and which are arranged, respectively, on one side and the other side in the X direction with respect to the overlap part.

The high potential electrode 52 is arranged between the first piezoelectric layer 41 and the second piezoelectric layer 42. The individual part 52a of the high potential electrode 52 is overlapped with the pressure chamber 10 in the Z direction. A length L2 in the X direction of the individual part 52a is shorter than a length L10 in the X direction of the pressure chamber 10. The pressure chamber 10 has an overlap part overlapped with the individual part 52a in the Z direction and outside parts which are not overlapped with the individual part 52a in the Z direction and which are arranged, respectively, on one side and the other side in the X direction with respect to the overlap part.

The driving electrode 53 is arranged between the second piezoelectric layer 42 and the third piezoelectric layer 43. The driving electrode 53 has an overlap part which is overlapped with the pressure chamber 10 in the Z direction, and outside parts which are not overlapped with the pressure chamber 10 in the Z direction and which are arranged, respectively, on one side and the other side in the X direction with respect to the overlap part. A length L3 in the X direction of the driving electrode 53 is longer than the length L2 in the X direction of the individual part 52a and a length L4 in the X direction of the individual part 54a, and is shorter than a length L1 in the X direction of the driving electrode 51. A length in the X direction of the outside part of the driving electrode 53 is shorter than a length in the X direction of the outside part of the driving electrode 51.

A difference between the length L3 and the length L2 and a difference between the length L3 and the length L4 are greater than a stacking tolerance (for example, in a range of 20 μm to 30 μm).

The high potential electrode 54 is arranged between the third piezoelectric layer 43 and the fourth piezoelectric layer 44. The individual part 54a of the high potential electrode 54 is overlapped with the pressure chamber 10 in the Z direction. The length L4 in the X direction of the individual part 54a is same as the length L2 in the X direction of the individual part 52a, and is shorter than the length L10 in the X direction of the pressure chamber 10. The pressure chamber 10 has an overlap part overlapped with the individual part 54a in the Z direction and outside parts which are not overlapped with the individual part 54a in the Z direction and which are arranged, respectively, on one side and the other side in the X direction with respect to the overlap part.

The low potential electrode 55 is arranged between the fourth piezoelectric layer 44 and the ink separating layer 45, and on a surface, of the fourth piezoelectric layer 44, on a side opposite to a side at which the third piezoelectric layer 43 is arranged. Two individual parts 55a of the low potential electrode 55 are arranged, respectively, on one side and the other side in the X direction with respect to the pressure chamber 10, and each of the two individual parts 55a has an overlap part overlapped, in the Z direction, with the one end or the other end in the X direction of the pressure chamber 10. Further, the two individual parts 55a are overlapped, in the Z direction with one end and the other end in the X direction of the individual part 54a of the high potential electrode 54, respectively. In other words, the individual part 54a of the high potential electrode 54 has a central part 54x which is not overlapped with the individual part 55a in the Z direction, and both end parts 54y in the X direction which are overlapped with the two individual parts 55a in the Z direction, respectively.

One end in the X direction of the driving electrode 53 is positioned, in the X direction, between one end in the X direction of the driving electrode 51 and one end in the X direction of the individual part 52a of the high potential electrode 52, and between the one end in the X direction of the driving electrode 51 and one end in the X direction of the individual part 54a of the high potential electrode 54. The other end in the X direction of the driving electrode 53 is positioned, in the X direction, between the other end in the X direction of the driving electrode 51 and the other end in the X direction of the individual part 52a of the high potential electrode 52, and between the other end in the X direction of the driving electrode 51 and the other end in the X direction of the individual part 54a of the high potential electrode 54.

In the center in the X direction of the pressure chamber 10, the driving electrode 51, the individual part 52a of the high potential electrode 52, the driving electrode 53 and the individual part 54a of the high potential electrode 54 are overlapped with one another in the Z direction.

A part, in the first piezoelectric layer 41, which is interposed between the driving electrode 51 and the individual part 52a of the high potential electrode 52 in the Z direction is referred to as a first active part 61. A part, in the second piezoelectric layer 42, which is interposed between the individual part 52a of the high potential electrode 52 and the driving electrode 53 in the Z direction is referred to as a second active part 62. A part, in the third piezoelectric layer 43, which is interposed between the driving electrode 53 and the individual part 54a of the high potential electrode 54 in the Z direction is referred to as a third active part 63. The active parts 61 to 63 are overlapped with one another in the Z direction.

At each of the both end parts in the X direction of the pressure chamber 10, the driving electrode 51, the driving electrode 53 and the individual part 55a of the low potential electrode 55 are overlapped with one another in the Z direction. Further, the driving electrode 51 and the individual part 55a of the low potential electrode 55 are overlapped with one another in the Z direction on each of the one side and the other side in the X direction with respect to the pressure chamber 10.

Parts, in the first to fourth piezoelectric layers 41 to 44, which are interposed between the driving electrode 51 and the individual part 55a of the low potential electrode 55 in the Z direction are referred to as a fourth active part 64. The fourth active part 64 is provided as two fourth active parts 64 which are positioned on the one side and the other side in the X direction with respect to the pressure chamber 10, and the first to third active parts 61 to 63 are interposed between the two fourth active parts 64 in the X direction.

Parts in the first and second piezoelectric layers 41 and 42, which are interposed between the driving electrode 51 and the driving electrode 53 in the Z direction are referred to as a non-active part 69. The non-active part 69 is provided as two non-active parts 69 which are positioned at the both ends in the X direction of the pressure chamber 10, the active parts 61 and 62 are interposed between the two non-active parts 69 in the X direction, and the two non-active parts 69 are interposed between the two fourth active parts 64 in the X direction. Namely, each of the two non-active parts 69 are interposed, in the X direction, between one of the two fourth active parts 64 and the active parts 61 and 62.

Parts, in the third and fourth piezoelectric layers 43 and 44, which are interposed between the driving electrode 53 and the individual parts 55a of the low potential electrode 55 in the Z direction are referred to as a fifth active part 65. The fifth active part 65 is provided as two fifth active parts 65 which are positioned at the both ends in the X direction of the pressure chamber 10, the active part 63 is interposed between the two fifth active parts 65 in the X direction, and the two fifth active parts 65 are interposed between the two fourth active parts 64 in the X direction. Namely, each of the two fifth active parts 65 is interposed, in the X direction, between one of the two fourth active parts 64 and the active part 63. The two fifth active parts 65 are overlapped with the two non-active parts 69 in the Z direction, respectively.

A length W5 in the X direction of the fifth active part 65 is same as a length W9 in the X direction of the non-active part 69, and is shorter than a length W4 in the X direction of the fourth active part 64.

The first to third active parts 61 to 63 are overlapped with the pressure chamber 10 in the Z direction. Each of the two non-active parts 69 and the two fifth active parts 65 has an overlap part overlapped with the pressure chamber 10 in the Z direction, and outside part which is not overlapped with the pressure chamber 10 in the Z direction and which is arranged on one side or the other side in the X direction with respect to the overlap part. Each of the two fourth active parts 64 is not overlapped with the pressure chamber 10 in the Z direction and is arranged on one side or the other side in the X direction with respect to the pressure chamber 10.

The pressure chamber 10 is not overlapped with the fourth active part 64 in the Z direction, and is overlapped with the first active part 61 to third active part 63, and fifth active part 65 and with the non-active part 69 in the Z direction.

The piezoelectric actuator 22 has, with respect to each of the plurality of pressure chambers 10, an actuator part 60 which is constructed of: the first active part 61, the second active part 62, the third active part 63, the two fourth active parts 64 and the two fifth active parts 65.

The first active part 61 and the third active part 63 are mainly polarized upward, and the second active part 62, the two fourth active parts 64 and the two fifth active parts 65 are mainly polarized downward.

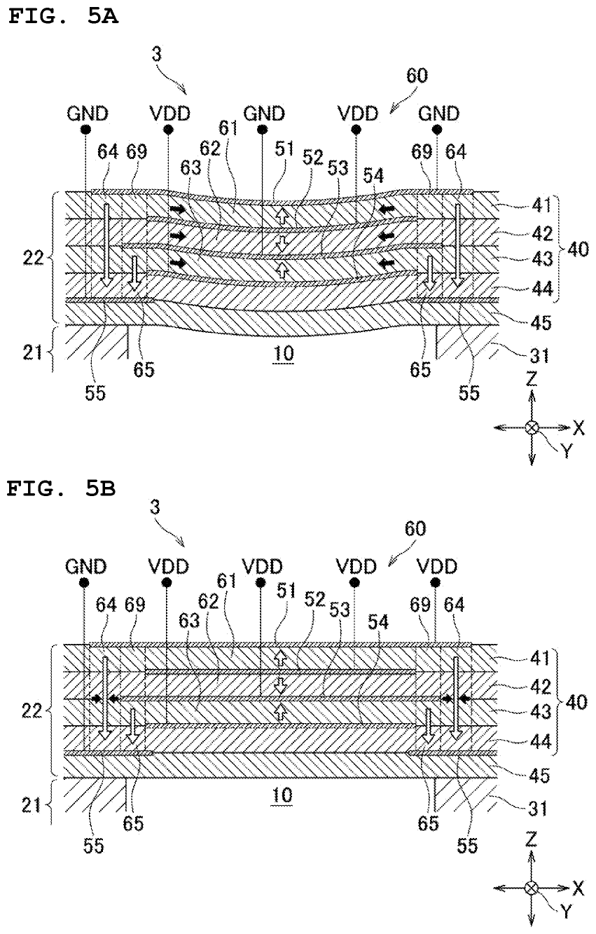

Here, an explanation will be given about an operation of the actuator part 60 in a case of causing the ink to be discharged from a certain nozzle 15 included in the plurality of nozzles 15, with reference to FIGS. 5A and 5B.

Before the printer 1 starts a recording operation, the low potential (GND potential) is applied to each of the driving electrodes 51 and 53, as depicted in FIG. 5A. In this situation, in the actuator part 60, an electric field which is oriented in a same direction as the polarization direction of each of the first to third active parts 61 to 63 is generated in the first to third active parts 61 to 63 due to a difference in the potential between the driving electrodes 51 and 53 and the high potential electrodes 52 and 54, and thus the first to third active parts 61 to 63 are contracted in a plane direction (a direction along the X direction and the Y direction). With this, a part which is included in a stacked body constructed of the piezoelectric body 40 and the ink separating layer 45 and which is overlapped, in the Z direction, with a certain pressure chamber 10, of the plurality of pressure chambers 10, corresponding to the certain nozzle 15 is deflexed to project toward the certain pressure chamber 10. In this situation, the volume of the certain pressure chamber 10 is made small as compared with a case that the stacked body is flat (see FIG. 5B).

In a case that the printer 1 starts the recording operation and that the ink is to be discharged from the certain nozzle 15, first, as depicted in FIG. 5B, the potential of the driving electrode 51 and the driving electrode 53 which correspond to the certain nozzle 15 are switched from the low potential (GND potential) to the high potential (VDD potential). In this situation, in the actuator part 60, the difference in potential is ceased to exist between the driving electrodes 51 and 53 and the high potential electrodes 52 and 54, thereby cancelling the contraction of the first to third active parts 61 to 63. On the other hand, a difference in potential is generated between the driving electrodes 51 and the low potential electrode 55 and between the driving electrode 53 and the low potential electrode 55, by which an electric field which is oriented in a same direction as the polarization direction of each of the two fourth active parts 64 and the two fifth active parts 65 is generated in each of the two fourth active parts 64 and the two fifth active parts 65, and thus each of the two fourth active parts 64 and the fifth active parts 65 is contracted in the plane direction. Note, however, that each of the two fourth active parts 64 and the two fifth active parts 65 has a function of suppressing a crosstalk, and each of the two fourth active parts 64 and the two fifth active parts 65 hardly contributes to the deformation of the actuator 60. Namely, in this situation, the part which is included in the stacked body and which are overlapped, in the Z direction, with the certain pressure chamber 10 corresponding to the certain nozzle 15 is not deflexed to project in a direction separating away from the certain pressure chamber 10, and the stacked body is in the flat state. With this, the volume of the certain pressure chamber 10 is made great as compared with the illustration of FIG. 5A.

Note that the term “crosstalk” means a phenomenon in which a variation in the pressure, in a certain pressure chamber 10, accompanying with deformation of the actuator part 60 is propagated to another pressure chamber 10 which is adjacent to the certain pressure chamber 10 in the X direction.

Afterward, as depicted in FIG. 5A, the potential of the driving electrode 51 and the potential of the driving electrode 53 which correspond to the certain nozzle 15 are switched from the high potential (VDD potential) to the low potential (GND potential). In this situation, in the actuator part 60, the difference in potential is ceased to exist between the driving electrodes 51 and the low voltage electrode 55 and between the driving electrode 53 and the low voltage electrode 55, thereby cancelling the contraction of the two fourth active parts 64 and the two fifth active parts 65. On the other hand, the difference in potential is generated between the driving electrodes 51 and 53 and the high potential electrodes 52 and 54, thereby generating, in the first to third active parts 61 to 63, the electric field which is oriented in the same direction as the polarization direction of the first to third active parts 61 to 63, and thus the first to third active parts 61 to 63 are contracted in the plane direction. With this, the part which is included in the stacked body and which is overlapped, in the Z direction, with the certain pressure chamber 10 corresponding to the certain nozzle 15 is deflexed to project toward the certain pressure chamber 10. In this situation, the volume of the certain pressure chamber 10 is greatly reduced, thereby applying a large pressure to the ink inside the certain pressure chamber 10, thereby causing the ink to be discharged from the certain nozzle 15.

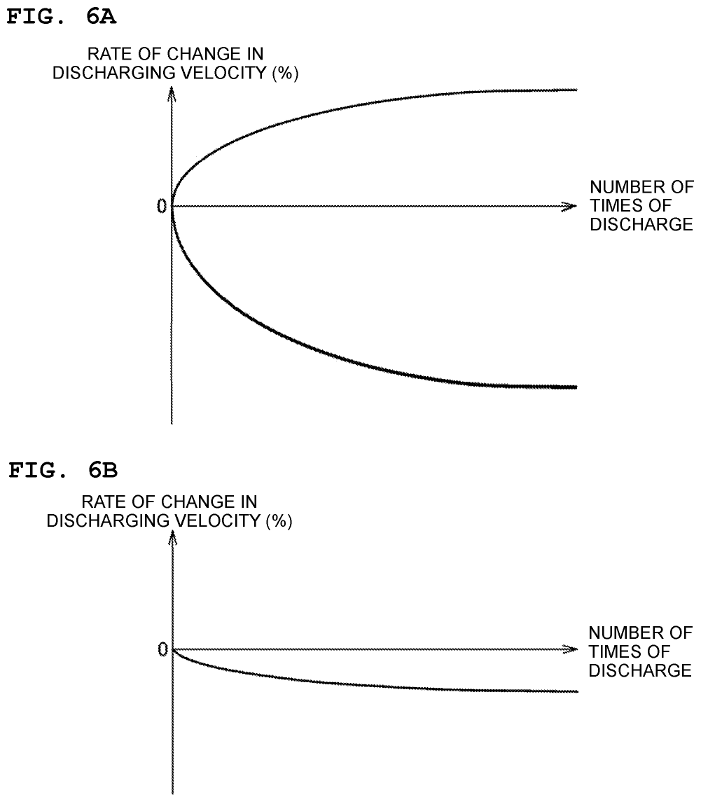

In a case that such an operation of the actuator part 60 is repeatedly performed, there is such a fear that a change in deforming characteristic (for example, a discharging velocity of the ink following the driving of the actuator part 60) might become great. In the present embodiment, however, since the actuator part 60 has not only the first to fourth active parts 61 to 64, but also the two non-active parts 69 and the two fifth active parts 65, it is possible to suppress the change in the deforming characteristic of the actuator part 60 as a whole, as depicted in FIG. 6B.

In FIGS. 6A and 6B, the horizontal axis indicates a number of times of discharge, and the vertical axis indicates a rate of change in the discharging velocity with a case that the number of times of discharge is 0 (zero) as the reference. In FIG. 6A, a curve on a plus side of the vertical axis is a conceptual view of a result of measurement performed such that an actuator part drives to discharge the ink from the nozzle 15 and the discharging velocity is measured every predetermined number of times of discharge, the actuator part having a configuration equivalent to a part, below the driving electrode 53, which includes the third active part 63 and the two fifth active parts 65 (that is, the lower half of the actuator part 60). In FIG. 6A, a curve on a minus side of the vertical axis is a conceptual view of a result of measurement performed such that an actuator part drives to discharge the ink from the nozzle 15 and the discharging velocity is measured every predetermined number of times of discharge, the actuator part having a configuration equivalent to a part, above the driving electrode 53, in which the first active part 61 and the two fourth active part 64 are provided via the two non-active parts 69 (that is, the upper half of the actuator part 60).

From FIG. 6A, it is appreciated that in the lower half part of the actuator part 60, the discharging velocity is increased (namely, an amount of the deformation of the lower half part is increased) as the number of times of discharge is increased (namely, the number of times of deformation of the lower half part is increased). On the other hand, in the upper half part of the actuator part 60, the discharging velocity is decreased (namely, the amount of deformation of the upper half part is decreased) as the number of times of discharge is increased. It is assumed that the increase in the amount of the deformation is due to the non-provision of the non-active part 69 (due to the provision of the fifth active part 65). It is assumed that the decrease in the deformation amount is due to the provision of the non-active part 69.

FIG. 6B is a view in which the plus side of the vertical axis of FIG. 6A (the deforming characteristic of the lower half part of the actuator part 60) and the minus side of the vertical axis of FIG. 6A (the deforming characteristic of the upper half part of the actuator part 60) are combined, and is a conceptual view indicating a deforming characteristic of the actuator part 60 of the present embodiment as a whole. It is appreciated that in the actuator part 60 as a whole, the change in the deforming characteristic is suppressed, by combining the chronological decrease in the deforming characteristic due to the provision of the non-active part 69 (the minus side of the vertical axis of FIG. 6A) and the chronological increase in the deforming characteristic due to the non-provision of the non-active part 69 (the provision of the fifth active part 65) (the plus side of the vertical axis of FIG. 6A).

Note that although the curve of FIG. 6B is on the minus side, the curve in FIG. 6B may be on the plus side, depending on the rate of change of the curve on the minus side of FIG. 6A.

As described above, according to the present embodiment, in the piezoelectric actuator 22 provided with the five electrodes 51 to 55 which are arranged at mutually different positions in the Z direction, the length L3 in the X direction of the driving electrode 53 is longer than the length L2 of the individual part 52a of the high potential electrode 52, and is longer than the length L4 in the X direction of the individual part 54a of the high potential electrode 54 (see FIG. 4). With this, in a case of manufacturing the piezoelectric actuator 22, even in a case that any positional deviation in the X direction occurs among the electrodes 51 to 55, a part, in the individual part 52a of the high potential electrode 52, which is not overlapped with the driving electrode 53 in the Z direction is less likely to be generated, and a part, in the individual part 54a of the high potential electrode 54, which is not overlapped with the driving electrode 53 in the Z direction is less likely to be generated. Accordingly, the configuration of the active parts 61 to 65 are less likely to differ among the manufactured piezoelectric actuators 22, and a variation in the deforming characteristic among the individual piezoelectric actuators 22 is less likely to occur.

Further, in the present embodiment, by making the length L3 in the X direction of the driving electrode 53 longer than the length L2 in the X direction of the individual parts 52a of the high potential electrode 52 and the length L4 in the X direction of the individual parts 54a of the high potential electrode 54, the actuator part 60 has not only the first to fourth active parts 61 to 64, but also the two non-active parts 69 and the two fifth active parts 65 (see FIG. 4). In this configuration, it is possible to suppress the change in the deforming characteristic in the actuator part 60 as a whole, by combining the chronological decrease in the deforming characteristic due to the provision of the non-active part 69 (the minus side of the vertical axis of FIG. 6A) and the chronological increase in the deforming characteristic due to the non-provision of the non-active part 69 (the provision of the fifth active part 65) (the plus side of the vertical axis of FIG. 6A) (see FIG. 6B).

In such a manner, according to the present embodiment, it is possible to suppress both the variation in the deforming characteristic among individual piezoelectric actuators and a chronological change in the deforming characteristic in each of the piezoelectric actuators.

The difference between the length L3 and the lengths L2 and L4 is greater than the stacking tolerance (for example, in a range of 20 μm to 30 μm). In this case, the variation in the deforming characteristic among individual piezoelectric actuators is reduced in a more ensured manner. Namely, in the case of manufacturing the piezoelectric actuator 22, even in a case that any positional deviation in the X direction occurs among the electrodes 51 to 55, the part, in the individual part 52a of the high potential electrode 52, which is not overlapped with the driving electrode 53 in the Z direction is less likely to be generated in a more ensured manner, and the part, in the individual part 54a of the high potential electrode 54, which is not overlapped with the driving electrode 53 in the Z direction is less likely to be generated in a more ensured manner.

The length W4 in the X direction of the fourth active part 64 is longer than the length W5 in the X direction of the fifth active part 65 (see FIG. 4). The fourth active part 64 has the function of suppressing the crosstalk; in a case that the length W4 is short, the effect of suppressing the crosstalk might be lowered. In view of this point, since the length W4 is long in the present embodiment, it is possible to achieve the effect of suppressing the crosstalk.

Each of the both end parts in the X direction of the individual part 54a of the high potential electrode 54 is overlapped with the individual part 55a of the low potential electrode 55 in the Z direction (see FIG. 4). With this, in a case of manufacturing the piezoelectric actuator 22, even in a case that any positional deviation in the X direction occurs in the electrodes 51 to 55, any gap in the X direction is less likely to be generated between the individual part 54a and the individual part 55a. Provided that such gap is generated, the gap functions as a non-active part and thus it is difficult to obtain the chronological increase in the deforming characteristic due to the non-provision of the non-active part 69 (the provision of the fifth active part 65) (on the plus side of the vertical axis of FIG. 6A), and thus it is difficult to suppress the change in the deforming characteristic of the actuator part 60 as a whole. In view of this point, since the above-described gap is less likely to be generated in the present embodiment, it is possible to obtain the chronological increase in the deforming characteristic due to the non-provision of the non-active part 69 (the provision of the fifth active part 65) (on the plus side of the vertical axis of FIG. 6A), and thus it is possible to suppress the change in the deforming characteristic of the actuator part 60 as a whole (see FIG. 6B).

In the head 3, the pressure chamber 10 is not overlapped with the fourth active part 64 in the Z direction, whereas the pressure chamber 10 is overlapped with the first active part 61 to third active part 63 and the fifth active part 65 in the Z direction (see FIG. 4). In this case, the deformations of the first active part 61 to third active part 63 act locally on the central part of the pressure chamber 10, as compared with a case that the pressure chamber 10 is not overlapped with the fifth active part 65 in the Z direction. With this, it is possible to change the volume of the pressure chamber 10 efficiently.

### Second Embodiment

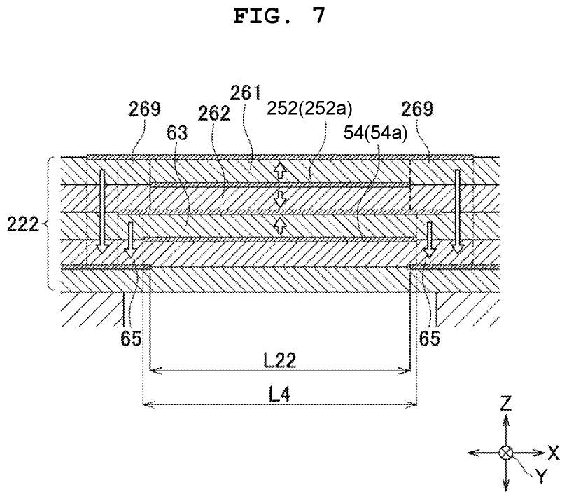

Next, an explanation will be given about a piezoelectric actuator 222 according to a second embodiment of the present disclosure, with reference to FIG. 7.

The piezoelectric actuator 222 according to the second embodiment has a configuration substantially same as the configuration of the piezoelectric actuator 22 (see FIG. 4) according to the first embodiment, except that a length L22 in the X direction of an individual parts 252a (an example of the “second electrode”) of a high potential electrode 252 and a length L4 in the X direction of an individual parts 54a of a high potential electrode 54 are mutually different.

The length L22 is shorter than the length L4. With this, a length in the X direction (=L22) of each of a first active part 261 and a second active part 262 is shorter than a length in the X direction (=L4) of a third active part 63. Further, a length in the X direction of a non-active part 269 is longer than a length in the X direction of the fifth active part 65.

Alternatively, the length L22 may be longer than the length L4. With this, the length in the X direction (=L22) of each of the first active part 261 and the second active part 262 may be longer than the length in the X direction (=L4) of the third active part 63. The length in the X direction of the non-active part 269 may be shorter than the length in the X direction of the fifth active part 65.

According to the second embodiment, the chronological change in the deforming characteristic may be suppressed further, as compared with the case that the length in the X direction of the individual part 252a of the high potential electrode 252 and the length in the X direction of the individual part 54a of the high potential electrode 54 are mutually same (see FIG. 4 of the first embodiment: L2=L4).

### (Modification)

While the invention has been described in conjunction with various example structures outlined above and illustrated in the figures, various alternatives, modifications, variations, improvements, and/or substantial equivalents, whether known or that may be presently unforeseen, may become apparent to those having at least ordinary skill in the art. Accordingly, the example embodiments of the disclosure, as set forth above, are intended to be illustrative of the invention, and not limiting the invention. Various changes may be made without departing from the spirit and scope of the disclosure. Therefore, the disclosure is intended to embrace all known or later developed alternatives, modifications, variations, improvements, and/or substantial equivalents. Some specific examples of potential alternatives, modifications, or variations in the described invention are provided below:

For example, the ink separating layer 45 may be omitted.

The liquid discharging head is not limited to being of the serial system, and may be of a line system.

The present disclosure is applicable also to facsimiles, copy machines, multifunction peripherals, etc., without being limited to printers. Further, the present disclosure is applicable also to a liquid discharging apparatus used for any other application than the image recording (for example, a liquid discharging apparatus which forms an electroconductive pattern by discharging an electroconductive liquid onto a substrate). Further, the piezoelectric actuator according to the present disclosure is applicable to any apparatus which is different from the liquid discharging apparatus.

What is claimed is:

1. A piezoelectric actuator comprising:
a first piezoelectric layer, a second piezoelectric layer, a third piezoelectric layer and a fourth piezoelectric layer stacked in a first direction in an order of the first piezoelectric layer, the second piezoelectric layer, the third piezoelectric layer, and the fourth piezoelectric layer; and
a first electrode arranged on a surface, of the first piezoelectric layer, on a side opposite to a side at which the second piezoelectric layer is arranged, a second electrode arranged between the first piezoelectric layer and the second piezoelectric layer, a third electrode arranged between the second piezoelectric layer and the third piezoelectric layer, a fourth electrode arranged between the third piezoelectric layer and the fourth piezoelectric layer, and a fifth electrode arranged on a surface, of the fourth piezoelectric layer, on a side opposite to a side at which the third piezoelectric layer is arranged, wherein:
the first to fifth electrodes are configured such that a high potential and a low potential lower than the high potential are selectively applied to the first electrode, the high potential is applied to the second electrode, the high potential and the low potential are selectively applied to the third electrode, the high potential is applied to the fourth electrode, and the low potential is applied to the fifth electrode;
a part, of the first piezoelectric layer, interposed between the first electrode and the second electrode in the first direction constitutes a first active part;
a part, of the second piezoelectric layer, interposed between the second electrode and the third electrode in the first direction constitutes a second active part;
a part, of the third piezoelectric layer, interposed between the third electrode and the fourth electrode in the first direction constitutes a third active part;
parts, of the first, second, third, and fourth piezoelectric layers, interposed between the first electrode and the fifth electrode in the first direction constitute two fourth active parts, the first, second, and third active parts being interposed between the two fourth active parts in a second direction orthogonal to the first direction;
a length in the second direction of the third electrode is longer than a length in the second direction of the second electrode, and is longer than a length in the second direction of the fourth electrode;
parts, of the first and second piezoelectric layers, interposed between the first electrode and the third electrode in the first direction constitute two non-active parts, each of the two non-active parts being interposed between one of the two fourth active parts and the first and second active parts in the second direction; and
parts, of the third and fourth piezoelectric layers, interposed between the third electrode and the fifth electrode in the first direction constitute two fifth active parts, each of the two fifth active parts being interposed between one of the two fourth active parts and the third active part in the second direction and being overlapped with one of the two non-active parts in the first direction.

2. The piezoelectric actuator according to claim 1, wherein the length in the second direction of the second electrode and the length in the second direction of the fourth electrode are mutually different.

3. The piezoelectric actuator according to claim 1, wherein a difference between the length in the second direction of the third electrode and the length in the second direction of the second electrode is greater than a stacking tolerance.

4. The piezoelectric actuator according to claim 1, wherein a difference between the length in the second direction of the third electrode and the length in the second direction of the fourth electrode is greater than a stacking tolerance.

5. The piezoelectric actuator according to claim 1, wherein a length in the second direction of each of the two fourth active parts in the second direction is longer than a length in the second direction of each of the two fifth active parts.

6. The piezoelectric actuator according to claim 1, wherein the fourth electrode has a central part which is not overlapped with the fifth electrode in the first direction, and both end parts in the second direction each of which is overlapped with the fifth electrode in the first direction.

7. A liquid discharging head comprising:
a channel member in which a channel including a nozzle and a pressure chamber communicating with the nozzle is formed; and
a piezoelectric actuator arranged on a surface, of the channel member, in which the pressure chamber is opened, wherein:
the piezoelectric actuator includes:
a first piezoelectric layer, a second piezoelectric layer, a third piezoelectric layer and a fourth piezoelectric layer stacked in a first direction in an order of the first piezoelectric layer, the second piezoelectric layer, the third piezoelectric layer, and the fourth piezoelectric layer; and
a first electrode arranged on a surface, of the first piezoelectric layer, on a side opposite to a side at which the second piezoelectric layer is arranged, a second electrode arranged between the first piezoelectric layer and the second piezoelectric layer, a third electrode arranged between the second piezoelectric layer and the third piezoelectric layer, a fourth electrode arranged between the third piezoelectric layer and the fourth piezoelectric layer, and a fifth electrode arranged on a surface, of the fourth piezoelectric layer, on a side opposite to a side at which the third piezoelectric layer is arranged;
the first to fifth electrodes are configured such that a high potential and a low potential lower than the high potential are selectively applied to the first electrode, the high potential is applied to the second electrode, the high potential and the low potential are selectively applied to the third electrode, the high potential is applied to the fourth electrode, and the low potential is applied to the fifth electrode;
a part, of the first piezoelectric layer, interposed between the first electrode and the second electrode in the first direction constitutes a first active part;
a part, of the second piezoelectric layer, interposed between the second electrode and the third electrode in the first direction constitutes a second active part;
a part, of the third piezoelectric layer, interposed between the third electrode and the fourth electrode in the first direction constitutes a third active part;
parts, of the first, second, third, and fourth piezoelectric layers, interposed between the first electrode and the fifth electrode in the first direction constitute two fourth active parts, the first, second, and third active parts being interposed between the two fourth active parts in a second direction orthogonal to the first direction;
a length in the second direction of the third electrode is longer than a length in the second direction of the second electrode, and is longer than a length in the second direction of the fourth electrode;
parts, of the first and second piezoelectric layers, interposed between the first electrode and the third electrode in the first direction constitute two non-active parts, each of the two non-active parts being interposed between one of the two fourth active parts and the first and second active parts in the second direction;
parts, of the third and fourth piezoelectric layers, interposed between the third electrode and the fifth electrode in the first direction constitute two fifth active parts, each of the two fifth active parts being interposed between one of the two fourth active parts and the third active part in the second direction and being overlapped with one of the two non-active parts in the first direction; and
the pressure chamber is not overlapped with the fourth active part in the first direction, and is overlapped with the first active part, the second active part, the third active part and each of the two fifth active parts in the first direction.
